(19) United States
(12) Patent Application Publication
(10) Pub. No.: US 2010/0031504 A1
(43) Pub. Date: Feb. 11, 2010

(54) METHOD OF MANUFACTURING PROBE CARD

(75) Inventors: Ho-Joon Park, Seoul (KR); Byeung-gyu Chang, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/349,305

(22) Filed: Jan. 6, 2009

(30) Foreign Application Priority Data
Aug. 11, 2008 (KR) 10-2008-0078635

(51) Int. Cl. G01R 3/00

(52) U.S. Cl. 29/874

(57) ABSTRACT

A method of manufacturing a probe card is disclosed. The method in accordance with an embodiment of the present invention can include coupling a thermoplastic resin board to one surface of a probe head, forming a plurality of terminals on the other surface of the probe head, coupling a metal board to the thermoplastic resin board, and forming a probe tip by etching the metal board selectively. The method of the present invention can protect the probe head while etching and reduce percent defective of the probe card.

### CROSS-REFERENCE TO RELATED APPLICATIONS

This application claims the benefit of Korean Patent Application No. 10-2008-0078635, filed with the Korean Intellectual Property Office on Aug. 11, 2008, the disclosure of which is incorporated herein by reference in its entirety.

### BACKGROUND

1. Technical Field

The present invention relates to a method of manufacturing a probe card.

2. Description of the Related Art

A probe card is an interface between an electronic test system and a semiconductor wafer. Its purpose is to provide an electrical path between the test system and the circuits on the wafer, thereby permitting the testing and validation of the circuits at the wafer level, usually before they are diced, after wafer fabrication of semiconductor manufacturing processes.

It consists, normally, of a printed circuit board (PCB), a probe head and a probe tip. The probe card is manufactured in a way that it connects a terminal being disposed on one side of the probe head to the printed circuit board, and has the probe tip on the other side thereof. Usually, it is formed with a ceramic material board and a silicon wafer.

More specifically, the probe tip will be formed by repeating processes such as a photo-lithography process, a dry etching process, a metal thin-film deposition process and a plating process to the silicon wafer. After these processes, the silicon wafer is bonded to the probe head, which is made of a ceramic material and has bumps therein, and then the silicon wafer is removed.

Since this process is usually done in 300° C., the ceramic board and the silicon wafer are heated. Not only is the bonding process of the silicon wafer and the probe head being made of a ceramic material difficult due to different rates of thermal expansion between the ceramic board and the silicon wafer, but also the bonding quality may be deteriorated at room temperature, before removing the silicon wafer after the bonding. Also, while removing the silicon wafer, it is possible to damage the already-formed probe tip.

### SUMMARY

The present invention provides a method of manufacturing a quality probe card through a simple process.

The present invention also provides a method of manufacturing a probe card that can protect a probe head by using a thermoplastic resin.

An aspect of the present invention provides a method of manufacturing a probe card. In accordance with an embodiment of the present invention, the method can include coupling a thermoplastic resin board to one surface of a probe head, forming a plurality of terminals on the other surface of the probe head, coupling a metal board to the thermoplastic resin board, and forming a probe tip by etching a metal board selectively.

The probe head can be a ceramic board, and the thermoplastic resin board can further include scattered glass clothes.

The thermoplastic resin board can be one selected from a group consisting of liquid crystal polymer, polyetherimide (PEI), polyethersulfone (PES), polyetheretherketone (PEEK) and polytetrafluoroethylene (PTFE) or a combination thereof.

Another aspect of the present invention provides a method of manufacturing a probe card. In accordance with an embodiment of the present invention, the method can include coupling a thermoplastic resin board to both surfaces of a probe head, forming a plurality of terminals on the thermoplastic resin board coupled to the other surface of the probe head, coupling a metal board to the thermoplastic resin board coupled to one surface of the probe head, and forming a probe tip by etching the metal board selectively.

The probe head can be a ceramic board, and the thermoplastic resin board can further include scattered glass clothes.

The thermoplastic resin board can be one selected from a group consisting of liquid crystal polymer, polyetherimide (PEI), polyethersulfone (PES), polyetheretherketone (PEEK) and polytetrafluoroethylene (PTFE) or a combination thereof.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 shows a cross-sectional view of a probe card manufactured by a method of manufacturing the probe card in accordance with an embodiment of the present invention.

FIGS. 2 to 9 are cross-sectional views illustrating a process of manufacturing a probe card in accordance with an embodiment of the present invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first” and “second,” etc., may be used to describe various components, such components must not be limited to the above terms. The above terms are used only to distinguish one component from another. For example, a first component may be referred to as a second component without departing from the scope of rights of the present invention, and likewise a second component may be referred to as a first component. The term “and/or” encompasses both combinations of the plurality of related items disclosed and any item from among the plurality of related items disclosed.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Unless otherwise defined, all terms used herein, including technical or scientific terms, have the same meanings as those generally understood by those with ordinary knowledge in the field of art to which the present invention belongs. Such terms as those defined in a generally used dictionary are to be interpreted to have the meanings equal to the contextual meanings in the relevant field of art, and are not to be interpreted to have ideal or excessively formal meanings unless clearly defined in the present application.

Embodiments of the present invention will be described below in detail with reference to the accompanying drawings.

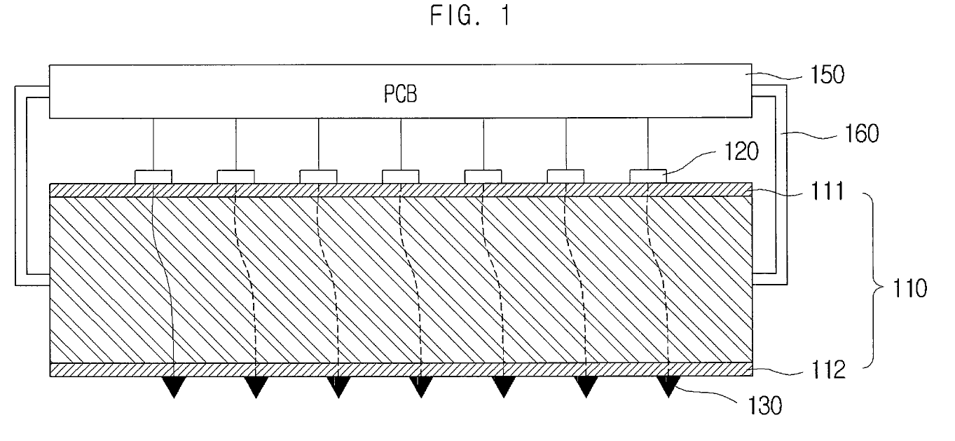

The structure of a probe card being manufactured by a method of manufacturing the probe card in accordance with an embodiment of the present invention will be described in detail with reference to FIG. 1, which shows a cross-sectional view of a probe card manufactured by a method of manufacturing the probe card in accordance with an embodiment of the present invention. In the embodiment, the probe card can include a printed circuit board (PCB) 150, a terminal 120, a probe head 110, an anchor 160 and a probe tip 130.

The printed circuit board 150 is electrically connected to a plurality of terminals 120 disposed on one side of the probe head 110. The printed circuit board 150 receiving an electrical signal from the terminal 120 can thus test a semiconductor circuit and a pad on a wafer-state semiconductor that are in contact with the probe tip 130.

One surface of the probe head 110 is equipped with the plurality of terminals 120, and the other side with a plurality of probe tips 130, which can be elastic. Also, the terminal 120 and the probe tip 130 are electrically connected through the probe head 110. Therefore, the probe tip 130 can receive an electrical signal by making physical contact with an object to be tested, and the received electrical signal will be transmitted to the printed circuit board 150 through the terminal 120 on the probe head 110. By analyzing the signal, validation of the object, e.g., the pad, to be tested can be determined. Here, the probe head 110 can be put in place with the printed circuit board 150 by an anchor 160.

In accordance with the probe head 110 of the probe card based on the embodiment of the present invention, each of thermoplastic resin boards 111 and 112 can be formed on each surface of the probe head 110, respectively. Here, the meaning of forming includes a notion of passivation. Moreover, all of the thermoplastic resin boards 111 and 112 can be formed on the other surface of the probe head 110, not on each surface of the probe card. That is, one surface of the probe head, having a probe tip formed thereon, is always protected by thermoplastic resin.

The thermoplastic resin can be any compound among liquid crystal polymer, which is inexpensive and has good thermal endurance and strength, polyetherimide (PEI), polyethersulfone (PES), polyetheretherketone (PEEK) and polytetrafluoroethylene (PTFE). It is also possible that the thermoplastic resin is a combination of the above compounds.

Here, the probe head 110 can be made of a ceramic material. And, the probe tip 130 can be formed by selectively etching a metal board. In such a process of etching, the probe head 110 can be affected by an etching solution.

However, in case the thermoplastic resin boards 111 and 112 are formed on both surfaces or the other surface of the probe head 110 only, the thermoplastic resin board will not be affected by the etching solution. Not only is the probe head 110 protected from the etching solution, but also electrical connection inside the board can function properly. Therefore, the problem of the probe head 110 being affected by the etching solution can be solved.

In order to form thermoplastic resin on both surfaces or the other surface of the probe head 110, a method of coupling a thermoplastic resin board on both surfaces or the other surface, or a method of applying the thermoplastic resin thereto can be used in accordance with an embodiment of the present invention.

Furthermore, glass clothes can be added to the thermoplastic resin board to be coupled or the thermoplastic resin to be applied. In case the glass clothes are evenly injected inside the thermoplastic resin, the elasticity and strength of the probe head 110 can be increased.

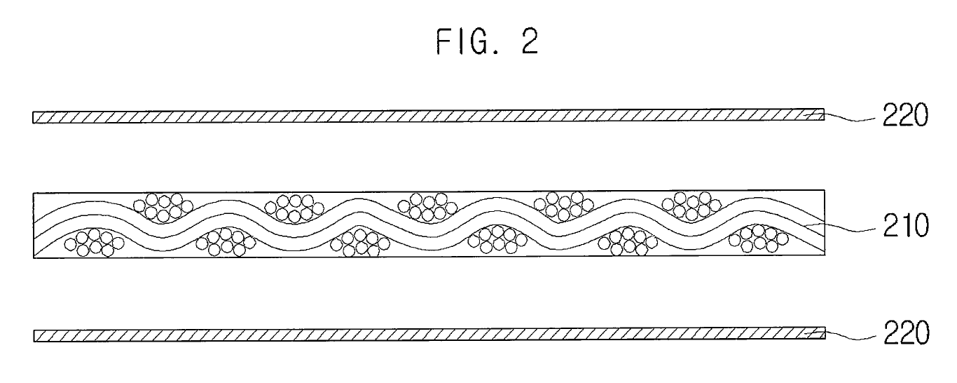

Below, a method of manufacturing a probe card in accordance with an embodiment of the present invention will be described with reference to FIGS. 2 to 9, which are cross-sectional views illustrating a process of manufacturing a probe card in accordance with an embodiment of the present invention.

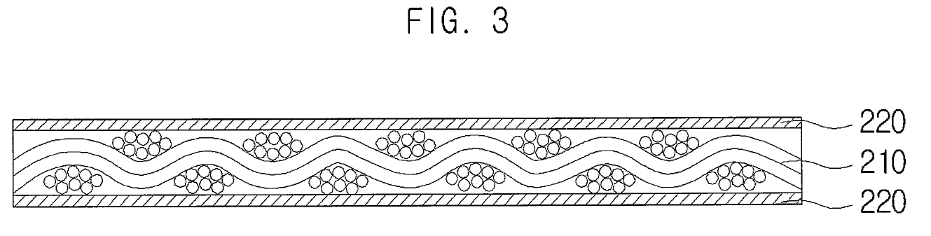

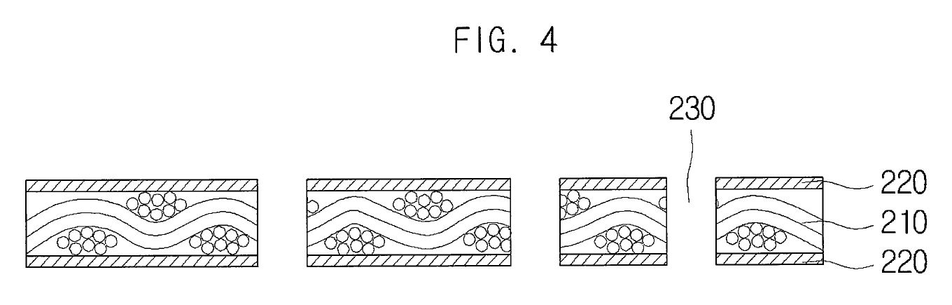

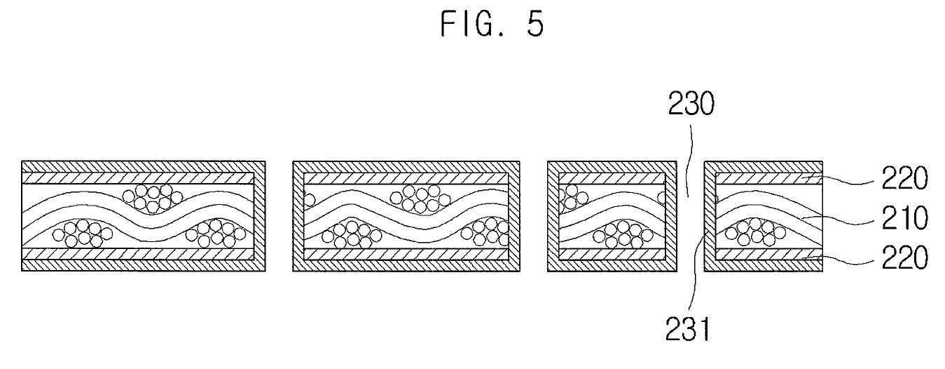

Referring to FIGS. 2 to 3, a copper foil 220 is formed on both surfaces of a thermoplastic resin board 210. As illustrated in FIG. 4, a via 230, which is for connecting different layers, is formed on the thermoplastic resin board 210, on which the copper foil 220 is formed on both surfaces thereof. Then, a plating layer 231 is formed on the thermoplastic resin board 210, on which the copper foil 220 is formed on both surfaces thereof, as illustrated in FIG. 5.

As such, the process of manufacturing a probe card for electrical connection of the terminal is actually a process for providing an electrical path between the terminal 250 and the probe tip 270 through the probe head 240. The probe tip 270 receives an electrical signal by being in contact with an object to be tested, and the inputted electrical signal is then transmitted to a printed circuit board through the terminal 250, which is disposed on the probe head 240. The electrical signal transmitted to the printed circuit board is analyzed, thereby permitting validation of the object, e.g., the pad at the wafer level.

Here, scattered glass clothes can be added to the thermoplastic resin board 210. In case the glass clothes are evenly injected inside the thermoplastic resin, the elasticity and strength of the thermoplastic resin board 210 can be increased.

The thermoplastic resin board 210 can be a compound among liquid crystal polymer, which is inexpensive and had good thermal endurance and strength, polyetherimide (PEI), polyethersulfone (PES), polyetheretherketone (PEEK) and polytetrafluoroethylene (PTFE). Moreover, the thermoplastic resin can be a combination of the above compounds.

The process of manufacturing a probe card illustrated in FIGS. 2 to 5 only represents an embodiment of the process of manufacturing a probe card for electrical connection of the terminal. It shall be appreciated that the process is not restricted to the above embodiment and there can be a variety of methods within the technical scope of the present invention.

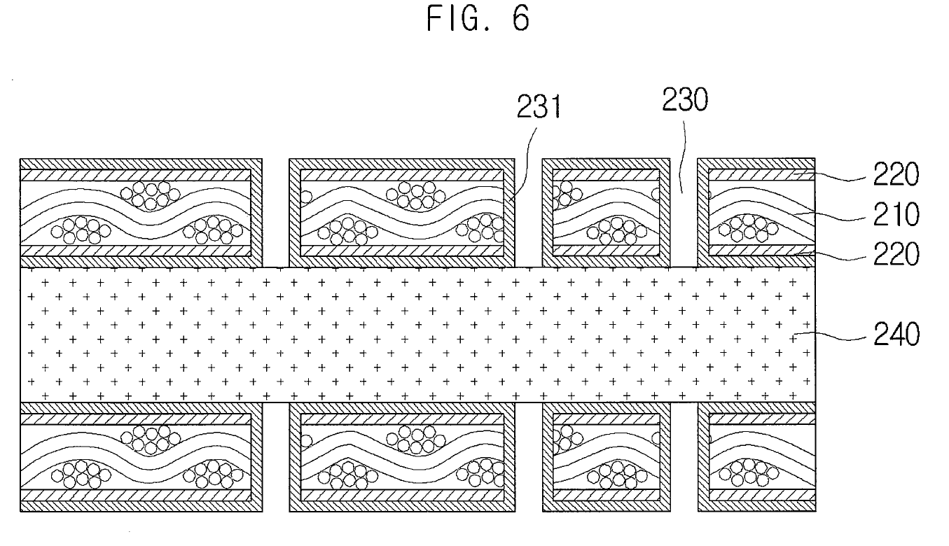

Referring to FIG. 6, the thermoplastic resin board 210 is coupled to both surfaces of the probe head 240, after the process for providing an electrical path to the terminal. Here, it shall be evident that the meaning of coupling includes a notion of passivation. As such, although the thermoplastic resin board 210 can be coupled to both surfaces of the probe head 240, it is also possible to couple the thermoplastic resin board 210 to one surface of the probe head 240 only. Hereinafter, however, an embodiment of coupling the thermoplastic resin board 210 to both surfaces of the probe head 240 will be described.

In accordance with the embodiment, the probe head 240 can be a ceramic board.

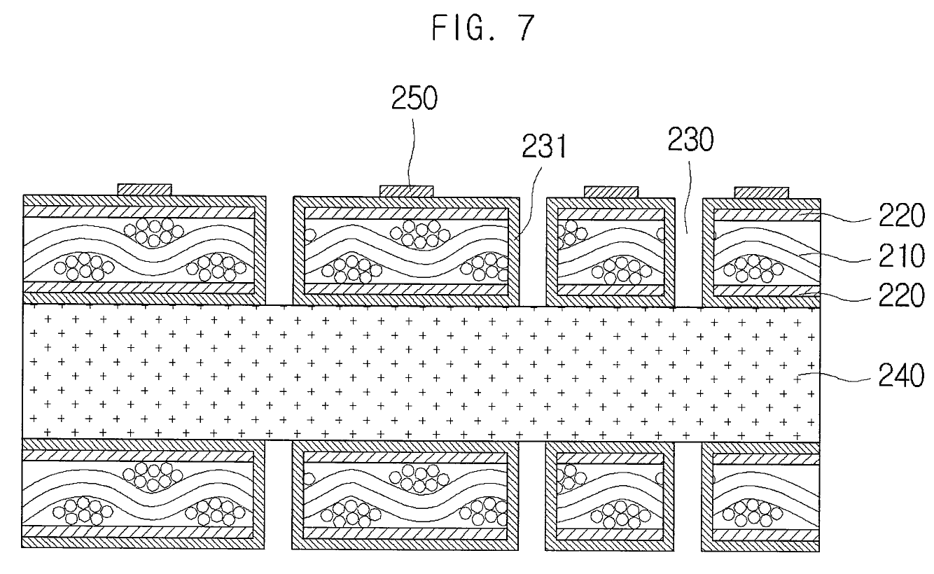

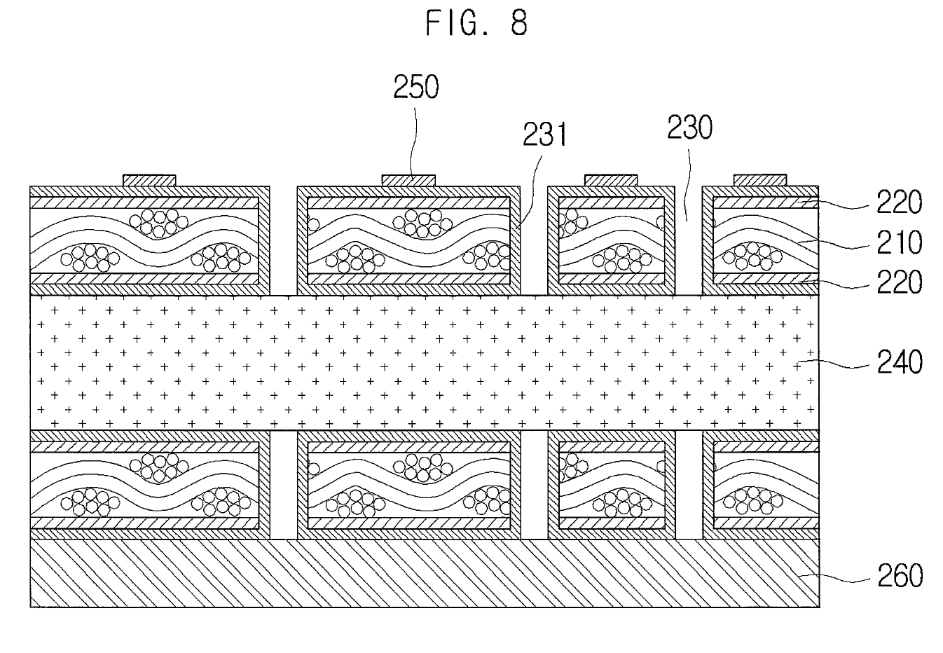

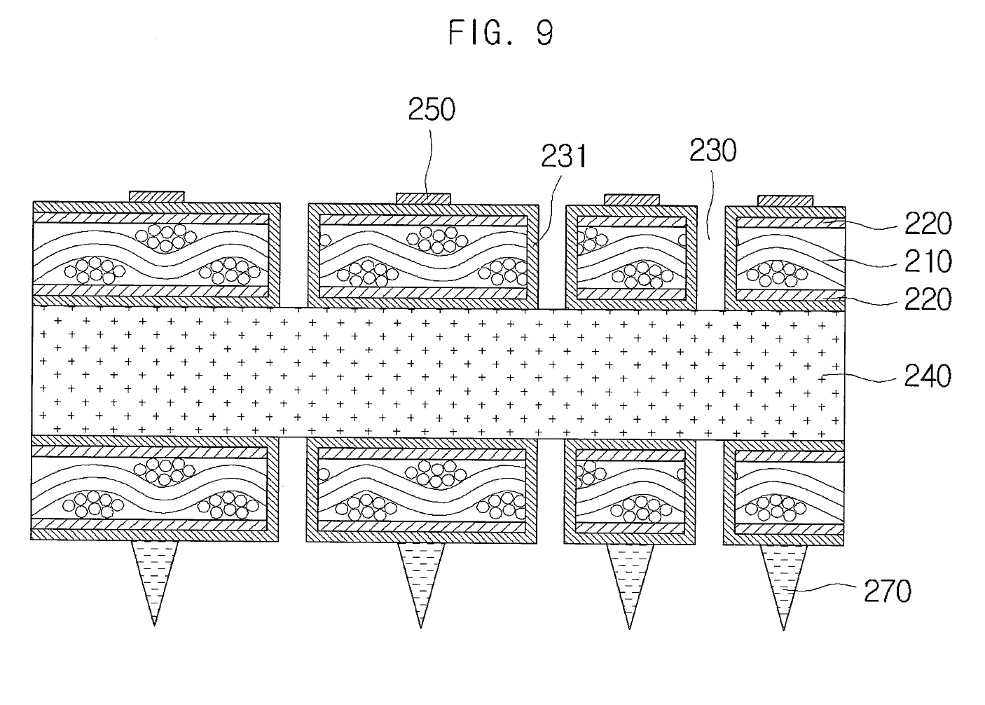

Next, as illustrated in FIG. 7, a plurality of terminal 250 are formed on the thermoplastic resin board 210, which is coupled to the other surface of the probe head 240. As illustrated in FIG. 8, a metal board 260 is coupled to the thermoplastic resin board 210, which is coupled to one surface of the probe head 240. A probe tip 270 can be formed by selectively etching the metal board 260, as shown in FIG. 9. A photo-lithography process and an etching process can be used for selectively etching the metal board 260. Through these processes, the probe tip 270 can be formed directly.

The thermoplastic resin board 210 has a good bonding strength with the metal board 260 and is not affected by an etching solution. Thus, the thermoplastic resin board 210 can protect the ceramic probe head and provide an electrical path.

By forming the probe tip 270 by directly coupling the metal board 260, which becomes the material for the probe tip 270, to the probe head 240, on which the thermoplastic resin board 210 forms a protective layer, the manufacturing process becomes simpler, improving the productivity and reducing the production cost. Furthermore, not only does it prevent a defect that may occur during a process of removing a silicone mold, but also the probe head 240 can be protected from the etching solution used in the manufacturing process since a protective layer is formed on the probe head 240 with the thermoplastic resin board 210.

While the spirit of the invention has been described in detail with reference to a particular embodiment, the embodiment is for illustrative purposes only and shall not limit the invention. It is to be appreciated that those skilled in the art can change or modify the embodiment without departing from the scope and spirit of the invention. As such, many embodiments other than that set forth above can be found in the appended claims.

What is claimed is:

1. A method of manufacturing a probe card, the method comprising:
coupling a thermoplastic resin board to one surface of a probe head;
forming a plurality of terminals on the other surface of the probe head;
coupling a metal board to the thermoplastic resin board; and
forming a probe tip by etching the metal board selectively.

2. The method of claim 1, wherein the probe head is a ceramic board.

3. The method of claim 1, wherein the thermoplastic resin board further comprises scattered glass clothes.

4. The method of claim 1, wherein the thermoplastic resin board is one selected from a group consisting of liquid crystal polymer, polyetherimide (PEI), polyethersulfone (PES), polyetheretherketone (PEEK) and polytetrafluoroethylene (PTFE) or a combination thereof.

5. A method of manufacturing a probe card, the method comprising:
coupling a thermoplastic resin board to both surfaces of a probe head;
forming a plurality of terminals on the thermoplastic resin board coupled to the other surface of the probe head;
coupling a metal board to the thermoplastic resin board coupled to one surface of the probe head; and
forming a probe tip by etching the metal board selectively.

6. The method of claim 5, wherein the probe head is a ceramic board.

7. The method of claim 5, wherein the thermoplastic resin board further comprises scattered glass clothes.

8. The method of claim 5, wherein the thermoplastic resin board is one selected from a group consisting of liquid crystal polymer, polyetherimide (PEI), polyethersulfone (PES), polyetheretherketone (PEEK) and polytetrafluoroethylene (PTFE) or a combination thereof.
